(19) United States
(12) Patent Application Publication
(10) Pub. No.: US 2026/0336063 A1
(43) Pub. Date: Oct. 29, 2026

(54) CAPACITIVE SENSOR SYSTEM FOR CHEMICAL MECHANICAL POLISHING SYSTEM AND METHOD

(71) Applicant: Taiwan Semiconductor Manufacturing Co., Ltd., Hsinchu (TW)

(72) Inventors: Jin-Hao Jhang, Chubei City (TW); Jhih Guang Wu, Kaohsiung City (TW); Chih Hung Chen, Hsinchu (TW); Wei-Yen Woon, Taoyuan (TW); Chu-Hsuan Sha, Taipei City (TW)

(21) Appl. No.: 19/732,428

(22) Filed: Jul. 6, 2026

Related U.S. Application Data
(63) Continuation of application No. 19/095,770, filed on Mar. 31, 2025.
(60) Provisional application No. 63/719,186, filed on Nov. 12, 2024.

(51) Int. Cl. B24B 49/10; B24B 57/02; H10P 74/00; H10P 95/00

(52) U.S. Cl. CPC B24B 49/10; B24B 57/02; H10P 74/238; H10P 95/06

(57) ABSTRACT

In an embodiment, a polishing system may include a polishing platen. The polishing system may also include a polishing pad on the polishing platen, a polishing head configured to hold a wafer in contact with the polishing pad, a capacitive sensor configured to measure a capacitance of a dielectric film on the wafer during a polishing process, and a controller electrically connected to the capacitive sensor. The controller maybe be configured to adjust at least one polishing parameter based on the measured capacitance, and halt the polishing process when the measured capacitance is within a predetermined range corresponding to a target thickness of the dielectric film.

### PRIORITY CLAIM AND CROSS-REFERENCE

This application is a continuation of U.S. patent application Ser. No. 19/095,770, filed Mar. 31, 2025, entitled “CAPACITIVE SENSOR SYSTEM FOR CHEMICAL MECHANICAL POLISHING SYSTEM AND METHOD,” which claims the benefit of the following provisionally filed U.S. Patent application No. 63/719,186, filed on Nov. 12, 2024, and entitled “IN-SITU CAPACITIVE MEASUREMENT FOR DIELECTRIC FILM THICKNESS CONTROL IN CMP,” which applications are hereby incorporated herein by reference.

### BACKGROUND

Semiconductor devices are used in a variety of electronic applications such as personal computers, cell phones, digital cameras, and other electronic equipment. Semiconductor devices are typically fabricated by sequentially depositing insulating or dielectric layers, conductive layers, and semiconductor layers over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. As the minimum feature sizes are reduced, however, additional problems arise and should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2, 3, 4, and 5 illustrate various aspects of a semiconductor wafer and a chemical mechanical polishing (CMP) system, according to some embodiments.

FIGS. 6, 7, and 8 illustrate top views of different configurations of platen-mounted sensors in a polishing system, according to some embodiments.

FIGS. 9, 10, 11, 12, and 13 illustrate various configurations of a polishing system with head-mounted sensors, according to some embodiments.

FIG. 14 illustrates a perspective view of example Complementary Field-Effect Transistors (CFETs) in accordance with some embodiments.

FIGS. 15 through 20 are views of intermediate stages in the manufacturing of CFETs in accordance with some embodiments.

FIG. 21 illustrates a sequence diagram illustrating the operation of a CMP system with capacitive sensing control in accordance with some embodiments.

FIG. 22 is a flowchart of a process in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Chemical mechanical polishing (CMP) is a process in semiconductor manufacturing, used to planarize surfaces and remove excess material. As semiconductor devices continue to shrink and become more complex, precise control of the CMP process becomes increasingly important. One area where this precision is particularly crucial is in the polishing of dielectric films, especially in the fabrication of complementary field-effect transistors (CFETs).

Various embodiments provide improved monitoring systems and methods may be used in CMP or other polishing or planarizing processes. Traditional CMP processes for dielectric films have relied on optical measurements or endpoint detection based on changes in motor current or friction. However, these methods can lack the sensitivity and accuracy required for advanced semiconductor processes, particularly when dealing with ultra-thin films or complex structures.

The present disclosure relates to systems and methods for in-situ capacitive measurement for film thickness control in CMP. CMP is a process in semiconductor manufacturing used to planarize surfaces and remove excess material. However, controlling the endpoint of CMP processes, particularly for dielectric films, has been challenging. Conventional methods often result in over-polishing or under-polishing, which can negatively impact device performance and yield.

This disclosure addresses the technical problem of precise thickness control during CMP by introducing an in-situ capacitive measurement technique. Unlike traditional optical or eddy current methods, this approach allows for real-time monitoring of film thickness, such as a dielectric film, without the need for a window in the polishing pad, which can cause defects or scratches. The capacitive measurement provides accurate feedback to the CMP control system, enabling precise endpoint detection and minimizing loss of the stop layer.

The systems and methods described herein offer several advantages over existing techniques. First, they provide non-destructive, in-situ measurement capabilities that can be easily integrated into existing CMP equipment. Second, the capacitive sensors can be calibrated using known references, such as dielectric constants and pad properties, allowing for accurate thickness measurements across various materials. Third, this approach is versatile and can be applied to a wide range of CMP processes, not limited to specific applications like complementary field-effect transistor (CFET) manufacturing.

By implementing this capacitive measurement technique, semiconductor manufacturers can achieve tighter control over dielectric film thickness, meeting increasingly stringent requirements for advanced node processes. For example, in applications where stop layer loss must be limited to less than 5 Å, this method enables precise control of the CMP process to meet such demanding specifications. Additionally, the cost-effective nature of this solution makes it an attractive option for improving CMP performance across various semiconductor manufacturing processes.

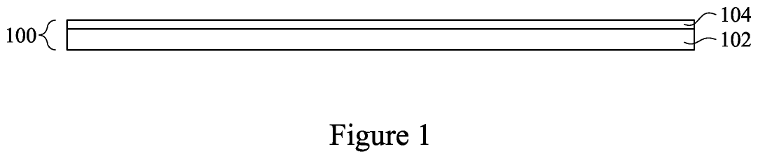

FIG. 1 illustrates a semiconductor wafer 100 that will be polished with a chemical mechanical polishing (CMP) system. The wafer 100 includes a semiconductor substrate 102 and a layer to be polished 104. In some cases, the semiconductor substrate 102 may include silicon, a III-V semiconductor material, or other suitable semiconductor materials. The semiconductor substrate 102 may serve as the foundation for various active devices and interconnect structures.

The layer to be polished 104 may be deposited on the semiconductor substrate 102 and may require planarization or removal through the CMP process. In some cases, the layer to be polished 104 may be a dielectric material, such as silicon oxide, silicon nitride, or low-k dielectric materials. In other cases, the layer to be polished 104 may be a conductive material, such as copper, aluminum, or tungsten. The composition of the layer to be polished 104 may depend on the specific manufacturing step and the desired final structure. In some embodiments, the layer to be polished 104 includes multiple layers of different compositions.

In some cases, the layer to be polished 104 may have a non-uniform thickness due to underlying structures or process variations experienced during deposition. For example, the layer to be polished 104 may be formed by depositing one or more materials into an opening through a dielectric layer using a chemical vapor deposition (CVD) process. Due to CVD process variations and the shapes of underlying structures, the layer to be polished 104 may have a non-uniform thickness and a non-planar surface.

The CMP process aims to planarize the layer to be polished 104, removing excess material and creating a smooth, uniform surface. This planarization may be critical for subsequent manufacturing steps, such as photolithography, etching, or the formation of additional layers. The in-situ capacitive measurement technique disclosed herein may be particularly useful for controlling the thickness of the layer to be polished 104 during the CMP process, especially when the layer to be polished 104 is a dielectric material.

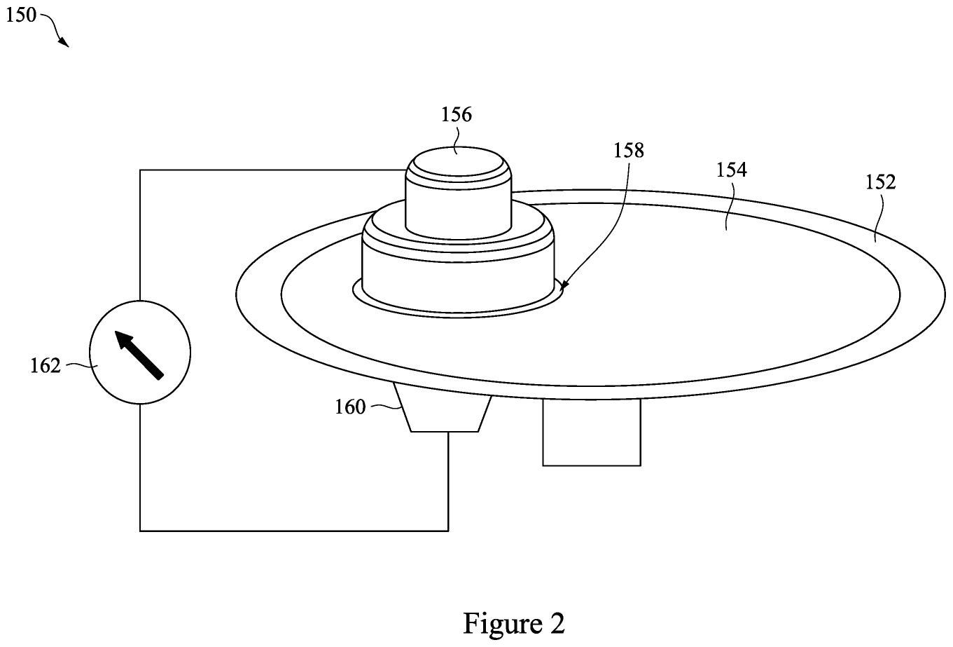

FIG. 2 illustrates a perspective view of a polishing system 150 for CMP. The polishing system 150 includes a polishing platen 152 that supports a polishing pad 154 on its upper surface. The polishing platen 152 may be configured to rotate the polishing pad 154 during a CMP process.

A polishing head 156 is positioned above the polishing pad 154 and holds a wafer 158 (sometimes referred to as a workpiece 158) for polishing operations. The polishing head 156 may include a carrier (not separately shown) configured to hold the wafer 158. In some cases, the carrier may be designed to securely hold the wafer 158 while allowing for the application of pressure during the polishing process. The polishing head 156 may include a retainer ring (not separately shown) mounted to the carrier. The retainer ring may help to contain the wafer 158 within the carrier and prevent it from sliding or moving during the polishing process. The polishing head 156 may be configured to apply downward pressure to hold the wafer 158 in contact with the polishing pad 154 during the CMP process. In some cases, the polishing head 156 may be configured to rotate the wafer 158 on the polishing pad 154 during the CMP process.

The polishing system 150 may further include a pad conditioner (not separately shown) on the polishing pad 154 to refresh the polishing pad 154. The pad conditioner may include a pad conditioner pad attached to a pad conditioner head. The pad conditioner head may be configured to rotate the pad conditioner pad on the surface of the polishing pad 154. The pad conditioner head may be configured to rotate the pad conditioner pad and the polishing platen 152 may be configured to rotate the polishing pad 154 in a same direction or opposite directions. In some embodiments, the polishing platen 152 is configured to rotate the polishing pad 154 during the CMP process, and the pad conditioner pad is not rotated. A pad conditioner arm is attached to the pad conditioner head and is configured to move the pad conditioner head and the pad conditioner pad in a sweeping motion across the polishing pad 154. In some embodiments, the pad conditioner pad comprises a substrate over which an array of abrasive particles is bonded using, for example, electroplating. The pad conditioner pad removes built-up wafer debris and excess slurry from the polishing pad 154 during CMP processing. In some embodiments, the pad conditioner pad acts as an abrasive for the polishing pad 154 to create a desired texture (such as, for example, grooves, or the like) against which the wafer 158 may be polished.

A platen-mounted sensor 160 is integrated into the polishing platen 152 beneath the polishing pad 154. This placement allows for non-intrusive monitoring of the wafer 158 during the polishing process. The sensor 160 utilizes capacitive technology, which enables it to measure the electrical capacitance of the wafer 158 as it undergoes polishing. This capacitive measurement is based on the principle that the dielectric properties of the wafer's surface layers change as material is removed during the CMP process.

As the polishing platen 152 rotates, the platen-mounted sensor 160 periodically passes beneath the wafer 158, creating a dynamic interaction between the sensor and the wafer's surface. This rotational movement allows the sensor to take measurements across different areas of the wafer, providing a comprehensive profile of the polishing progress. The capacitive measurements are made possible by the sensor's ability to detect changes in the electric field between itself and the wafer, which are influenced by the thickness and composition of the remaining film on the wafer's surface.

The arrangement of the platen-mounted sensor 160 offers several advantages. It allows for continuous, real-time monitoring of the polishing process without interfering with the physical contact between the wafer 158 and the polishing pad 154. Further, the sensor's position beneath the polishing pad 154 protects it from the harsh chemical and mechanical environment of the CMP process, ensuring reliable and consistent measurements throughout the operation. Also, this configuration enables the system to gather data on the entire wafer surface as it rotates, providing an accurate representation of the overall polishing uniformity.

The capacitive measurements obtained by the platen-mounted sensor 160 can be used to precisely control the endpoint of the CMP process, ensuring that the desired film thickness is achieved across the wafer 158. This level of control is particularly crucial in advanced semiconductor manufacturing processes, where even Angstrom-scale variations in film thickness can significantly impact device performance and yield.

The polishing system 150 incorporates a control mechanism including a controller 162, which is electrically connected to the platen-mounted sensor 160. The controller 162 continuously monitors and processes the real-time capacitance data collected by the platen-mounted sensor 160 during the CMP process. In some embodiments, the controller 162 is programmed with advanced algorithms that interpret the capacitance measurements, which directly correlate to the thickness of the dielectric film being polished on the wafer 158.

In some embodiments, the controller 162 automatically halts the polishing process when specific conditions are met. Specifically, the controller 162 may be configured to stop the CMP operation when the measured capacitance falls within a predetermined range. In some embodiments, this range may be calibrated to correspond to the desired final thickness of the dielectric film, taking into account factors such as the dielectric constant of the material, the initial film thickness, and the target thickness for the specific semiconductor device being fabricated.

The implementation of this feedback loop between the platen-mounted sensor 160 and the controller 162 enables the system and method to obtain a better level of precision in the polishing process. By continuously monitoring the capacitance in real-time, the system can make instantaneous decisions about the progress of the polishing, ensuring that the process stops at exactly the right moment to achieve the desired film thickness.

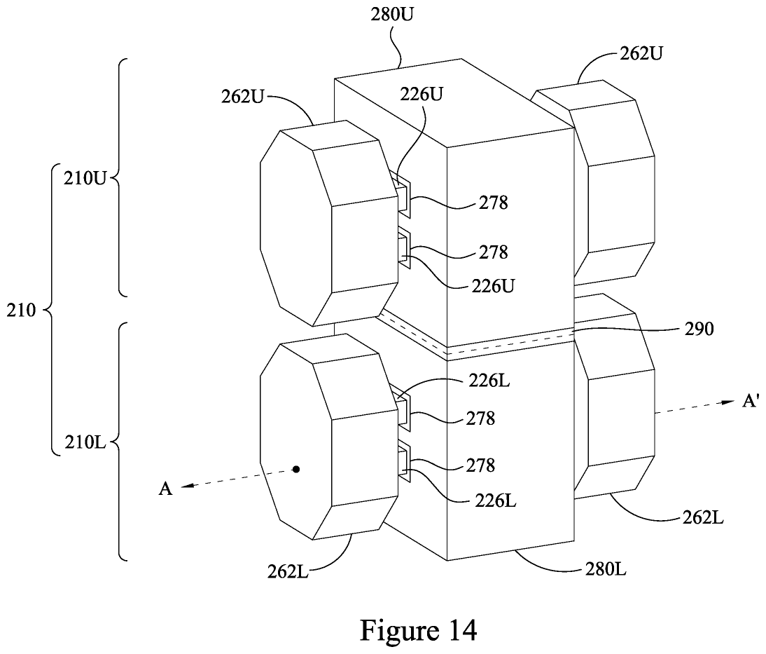

This precise control is important in advanced semiconductor manufacturing processes, such as those used in complementary field-effect transistor (CFET) fabrication (see, e.g. FIGS. 14-20), where even Angstrom-scale variations in dielectric film thickness can significantly impact device performance. The ability to halt the polishing process based on real-time capacitance measurements helps to minimize over-polishing or under-polishing, which can improve the uniformity and consistency of the final product across the entire wafer surface.

Moreover, the controller 162 may be programmed with additional capabilities to further enhance the CMP process. For instance, it could adjust polishing parameters such as pressure, rotational speed, or slurry flow rate based on the capacitance measurements, allowing for dynamic optimization of the polishing process as it progresses. This adaptive control can help compensate for variations in initial film thickness or polishing rate across different areas of the wafer, ultimately leading to improved planarization and more consistent results.

The combination of the platen-mounted sensor 160 and the controller 162 in the polishing system 150 may enable precise control and endpoint detection for the CMP process. This may be beneficial for polishing dielectric materials or other layers where traditional endpoint detection methods may be less effective. The capacitance measurements provided by the platen-mounted sensor 160 offer a non-destructive and in-situ method for monitoring the thickness and uniformity of the layer being polished on the wafer 158.

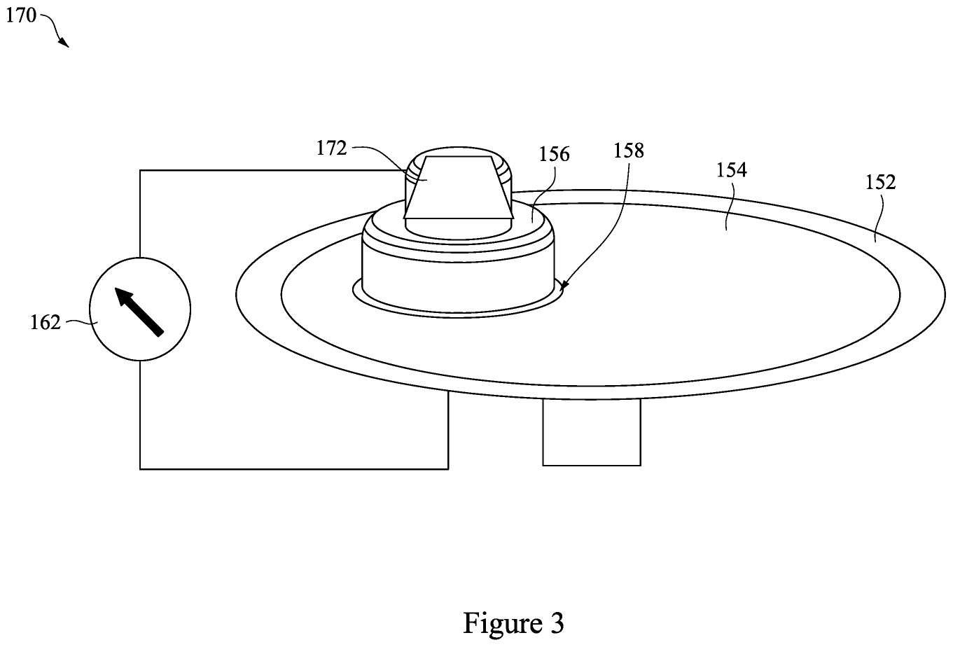

FIG. 3 illustrates a perspective view of a polishing system 170 for CMP in accordance with some embodiments. In this embodiment, the system 170 includes a head-mounted sensor 172 integrated into the polishing head 156.

The head-mounted sensor 172 may be a capacitive sensor configured to measure the capacitance of the wafer 158 during the polishing process. This configuration may offer advantages over the platen-mounted sensor setup. The head-mounted sensor 172 may provide more consistent and continuous measurements as the sensor moves with the wafer 158 throughout the polishing process. In addition, the proximity of the sensor to the wafer 158 may allow for more accurate and sensitive capacitance measurements.

The head-mounted sensor 172 may be integrated directly into the polishing head 156. This integration may allow for precise positioning of the sensor relative to the wafer 158, potentially improving the accuracy and reliability of the capacitance measurements. In some cases, the head-mounted sensor 172 may be positioned within the carrier or the retainer ring to optimize its proximity to the wafer 158.

The controller 162 may be electrically connected to the head-mounted sensor 172. The capabilities of the controller 162 may be similar to those described above in FIG. 2 and the description is not repeated herein. The controller 162 may be configured to receive and process the capacitance measurements from the head-mounted sensor 172. Based on these measurements, the controller 162 may adjust various polishing parameters or determine when to halt the polishing process.

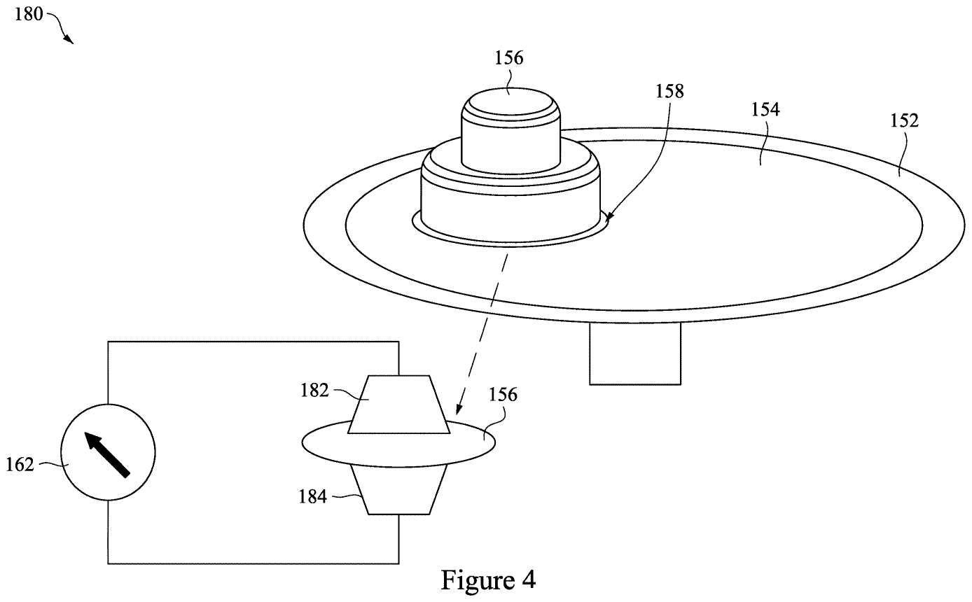

FIG. 4 illustrates a polishing system 180 for CMP. The polishing system 180 is similar to the polishing system 150 described earlier, but includes sensors adjacent to the polishing platen 152 for monitoring capabilities during the CMP process.

The polishing system 180 includes a first sensor 182 and a second sensor 184 that are configured to measure capacitance during the polishing process. The first sensor 182 and the second sensor 184 are not mounted to the polishing platen 152 or the polishing head 156 but are adjacent to the polishing platen 152. In this embodiment, the wafer 158 may be moved off of the polishing platen 152 to have the capacitance measured. In some embodiments, the wafer 158 may be moved off to have the capacitance measured at regular intervals to ensure the polishing process is stopped at desired thickness of the wafer 158 and/or the film being polished. The capabilities of the controller 162 may be similar to those described above in FIG. 2 and the description is not repeated herein. This arrangement allows for detecting the capacitance at multiple locations across a surface of the wafer 158.

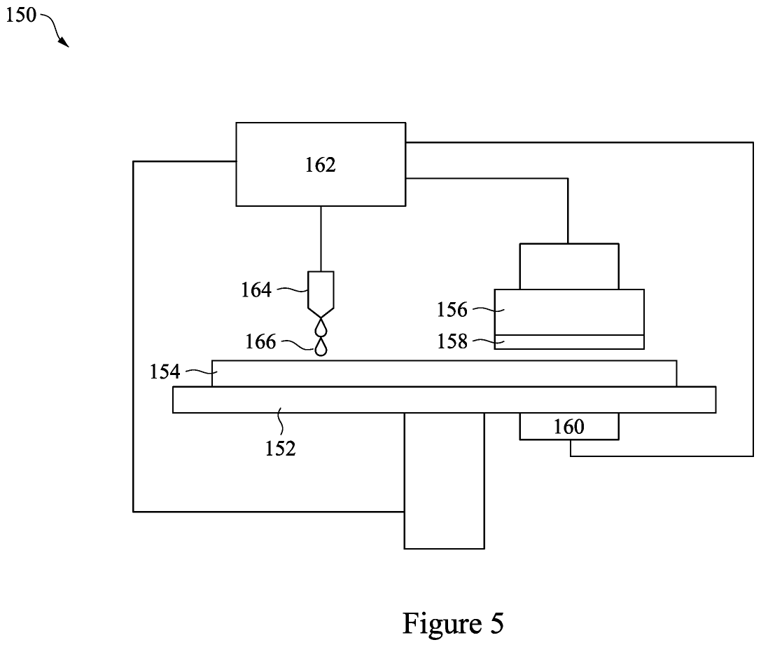

FIG. 5 illustrates a side view of the polishing system 150 of FIG. 2. The polishing system 150 of FIG. 5 further illustrates a slurry dispenser 164. The slurry dispenser 164 may be provided on the polishing pad 154 to deposit a slurry 166 onto the polishing pad 154. The polishing platen 152 may be configured to rotate the polishing pad 154, which may cause the slurry 166 to be distributed between the wafer 158 and the polishing pad 154.

The slurry 166 plays a role in the CMP process. In some cases, the composition of the slurry 166 may be dependent upon the types of materials present in the layer to be polished 104 that are desired to be polished or removed. The slurry 166 may include a reactant, an abrasive, a surfactant, and a solvent.

The reactant in the slurry 166 may be a chemical, such as an oxidizing agent or a reducing agent, which may chemically react with a material of the wafer 158 in order to assist the polishing pad 154 in abrading or removing material. The abrasive in the slurry 166 may include any suitable particulate that, in conjunction with the polishing pad 154, may be configured to polish or planarize the wafer 158.

In some cases, the slurry 166 may include a surfactant. The surfactant may be utilized to help disperse the reactant and the abrasive within the slurry 166, and to prevent or otherwise reduce the abrasive from agglomerating during the CMP process. A remaining portion of the slurry 166 may include the solvent. The solvent may be utilized to combine the reactant, the abrasive, and the surfactant, and allow the mixture to be moved and dispersed onto the polishing pad 154.

The slurry dispenser 164 may be configured to deposit the slurry 166 onto the polishing pad 154 prior to performing the removing process on the wafer 158. This may ensure that the slurry 166 is properly distributed between the wafer 158 and the polishing pad 154 before the polishing process begins. The rotation of the polishing platen 152 and the polishing pad 154 may further assist in distributing the slurry 166 evenly across the surface of the wafer 158 during the polishing process.

The integration of the slurry dispenser 164 into the polishing system 150 may allow for precise control over the amount and timing of slurry 166 deposition. In some cases, the controller 162 may be configured to control the operation of the slurry dispenser 164, coordinating the slurry deposition with other aspects of the polishing process, such as the rotation of the polishing platen 152 and the movement of the polishing head 156.

The polishing system 150 may incorporate capacitive measurement techniques to monitor the thickness of the film to be polished (may also be referred to as the target film) during the CMP process. In some embodiments, two electrodes may be positioned on either side of the film to measure its capacitance. For example, as illustrated in FIG. 5, one electrode may be set to the polishing head 156 and the other to the platen-mounted sensor 160.

The capacitance measurement may be performed using techniques including applying either DC or AC with a test voltage. The test voltage may vary depending on the specific method employed, and in some cases may range from about 1 mV to 10 V. As the CMP process typically only reduces the thickness of the film being polished, the system can separate the capacitance of the film from the overall system capacitance.

By measuring changes in capacitance over time, the system may determine the reduction in film thickness. This measurement technique may be applied at the start of the CMP process, enabling continuous monitoring of the target film thickness throughout the polishing operation. The controller 162 may use this real-time thickness data to ensure effective process control, adjusting polishing parameters as needed.

In some embodiments, the capacitance measurement may be performed at regular intervals during the polishing process. The frequency of these measurements may be adjusted based on factors such as the initial film thickness, the desired final thickness, and the overall polishing rate.

It should be noted that while this description focuses on the embodiment illustrated in FIG. 5, similar capacitance measurement techniques may be applied in other embodiments disclosed herein. The specific implementation may vary depending on the sensor configuration (e.g., platen-mounted, head-mounted, or adjacent sensors), but the underlying principle of using capacitance changes to monitor film thickness may remain consistent across different embodiments.

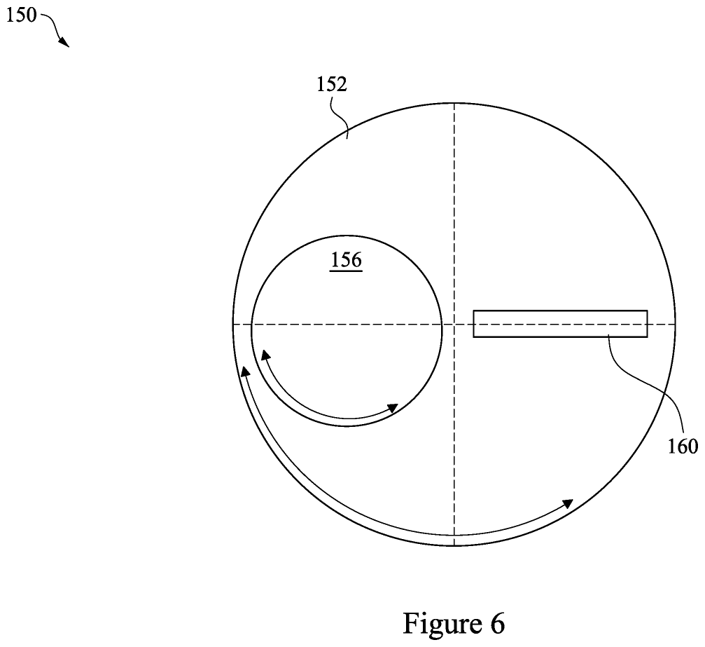

FIG. 6 illustrates a top view of the polishing system 150 configuration. In this configuration, the platen-mounted sensor 160 is rectangular-shaped in a top view and extends radially across a portion of the polishing platen 152. The platen-mounted sensor 160 may be positioned to intersect with the path of the polishing head 156 during operation.

The rectangular shape of the platen-mounted sensor 160 may allow for a larger sensing area compared to other sensor shapes. In some cases, this increased sensing area may provide more comprehensive capacitance measurements of the wafer 158 during the polishing process.

The radial arrangement of the platen-mounted sensor 160 across the polishing platen 152 may enable the sensor to take measurements at various points along the radius of the wafer 158 as the polishing platen 152 rotates. This configuration may allow for detection of capacitance variations across different regions of the wafer 158, potentially providing insights into the uniformity of the polishing process.

The positioning of the platen-mounted sensor 160 to intersect with the path of the polishing head 156 may ensure that the sensor passes under the wafer 158 during each rotation of the polishing platen 152. In some cases, this arrangement may allow for continuous monitoring of the wafer 158 throughout the CMP process.

The rectangular platen-mounted sensor 160 may be integrated into the polishing platen 152 beneath the polishing pad 154. This integration may allow for capacitance measurements to be taken through the polishing pad 154 without interfering with the physical contact between the polishing pad 154 and the wafer 158.

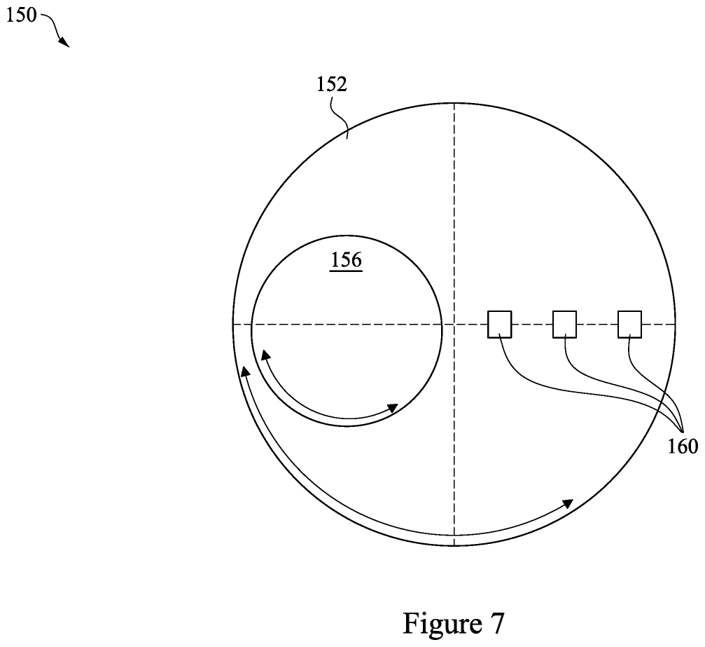

FIG. 7 illustrates a top view of a polishing system 150 configuration. In this configuration, multiple platen-mounted sensors 160 are arranged in a linear configuration across the polishing platen 152. The platen-mounted sensors 160 are square-shaped in a top view and positioned along a horizontal axis of the polishing platen 152.

The arrangement of the platen-mounted sensors 160 enables monitoring across different positions of the polishing platen 152 during operation. The square shape of the platen-mounted sensors 160 may provide a larger sensing area compared to other sensor shapes. In some cases, this increased sensing area may improve the accuracy and sensitivity of the capacitance measurements. The square shape may also allow for more efficient use of space on the polishing platen 152, potentially enabling the integration of a greater number of sensors.

The positioning of the platen-mounted sensors 160 along a horizontal axis of the polishing platen 152 may allow for measurements to be taken across the entire diameter of the wafer 158 during each rotation of the polishing platen 152. In some cases, this may provide a more comprehensive view of the polishing progress across the surface of the wafer 158.

The linear arrangement of the platen-mounted sensors 160 may also facilitate the detection of variations in the thickness of the layer to be polished across different regions of the wafer 158. By comparing measurements from different sensors as the wafer 158 passes over them, the controller 162 may be able to identify and compensate for non-uniformities in the polishing process.

In some cases, the multiple platen-mounted sensors 160 may be used in conjunction with the controller 162 to implement zone-based polishing control. The controller 162 may use the capacitance measurements from different sensors to adjust polishing parameters, such as pressure or rotation speed, for specific zones of the wafer 158. This may help to achieve more uniform material removal across the entire surface of the wafer 158.

The multiple sensor configuration of the platen-mounted sensors 160 may also provide redundancy in the measurement system. In some cases, if one sensor malfunctions or provides unreliable data, the remaining sensors may continue to provide sufficient information for the controller 162 to maintain effective control of the CMP process.

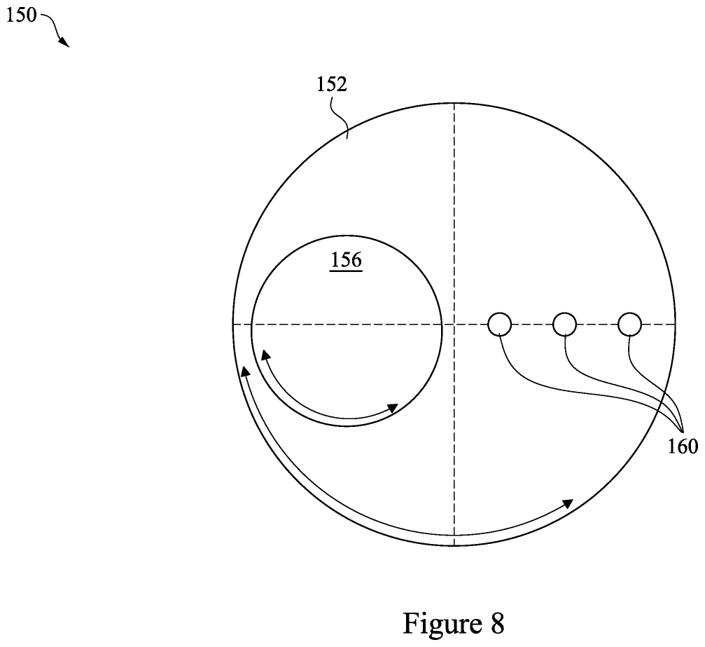

FIG. 8 illustrates a top view of a polishing system 150 configuration. In this configuration, multiple platen-mounted sensors 160 are arranged in a linear configuration across the polishing platen 152. The platen-mounted sensors 160 are circular-shaped in a top view and positioned along a horizontal axis that intersects both the polishing platen 152 and polishing head 156.

The circular shape of the platen-mounted sensors 160 may provide several advantages for capacitive measurements during the polishing process. In some cases, the circular shape may allow for a more uniform sensing area as the polishing platen 152 rotates, potentially resulting in more consistent measurements across the surface of the wafer.

The linear arrangement of the platen-mounted sensors 160 enables monitoring across different positions of the polishing platen 152 during operation. This configuration may allow for capacitive measurements at various points along the radius of the wafer as the polishing platen 152 rotates. In some cases, this arrangement may provide a more comprehensive profile of the layer to be polished across the wafer surface.

In some embodiments, the platen-mounted sensors 160 are spaced at regular intervals along the horizontal axis. This spacing may be optimized to provide adequate coverage of the wafer surface during the polishing process. In some cases, the spacing between the platen-mounted sensors 160 may be adjusted based on factors such as the size of the wafer, the desired measurement resolution, or the specific requirements of the polishing process.

The configuration of multiple circular platen-mounted sensors 160 may enhance the capacitive measurements during the polishing process in several ways. First, the use of multiple sensors may allow for simultaneous measurements at different locations across the wafer surface, potentially improving the accuracy and reliability of the thickness monitoring. Second, the circular shape of the sensors may provide consistent measurements regardless of the rotational position of the polishing platen 152.

In some cases, the controller may be configured to process the data from multiple platen-mounted sensors 160 to create a more comprehensive picture of the polishing progress. This may involve comparing measurements from different sensors, averaging readings, or using advanced algorithms to interpret the capacitive data and make real-time adjustments to the polishing process.

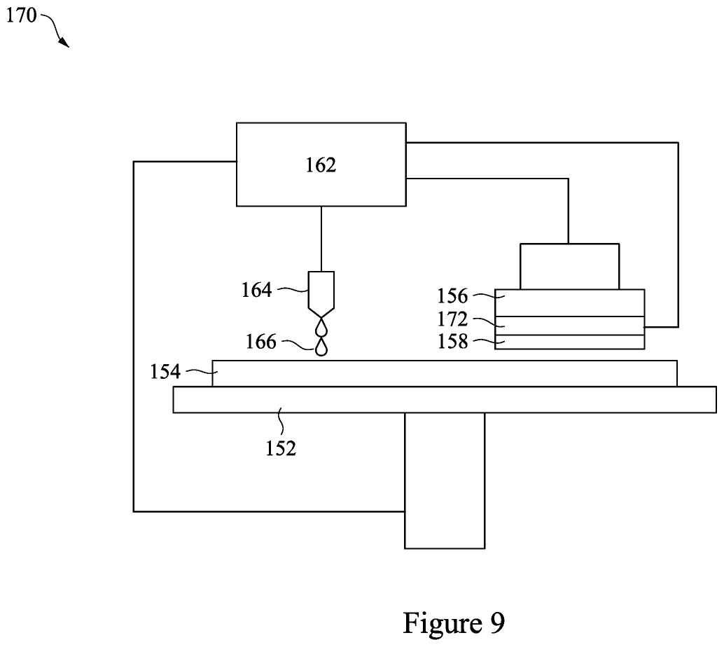

FIG. 9 illustrates a side view of the polishing system 170 with a head-mounted sensor 172 and a slurry dispenser 164. The polishing system 170 includes the polishing platen 152 that supports the polishing pad 154. The polishing head 156 is positioned above the polishing pad 154 and holds the wafer 158 for polishing operations.

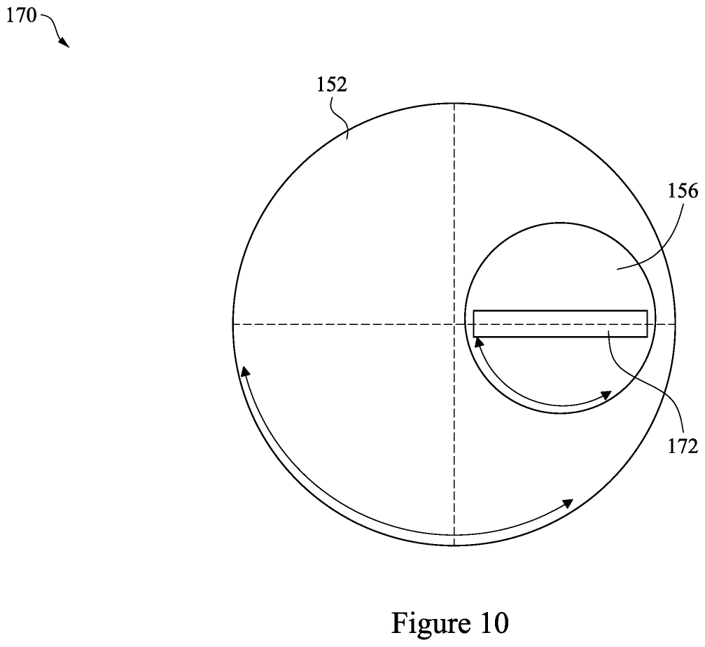

FIG. 10 illustrates a top view of the polishing system 170 configuration. In this configuration, the head-mounted sensor 172 is rectangular-shaped in a top view and is integrated into the polishing head 156. The head-mounted sensor 172 extends across a portion of the polishing head 156 and may be positioned to measure capacitance during the polishing process.

The rectangular shape of the head-mounted sensor 172 may provide several advantages for capacitive measurements during the polishing process. In some cases, the rectangular shape may allow for a larger sensing area compared to other sensor shapes, potentially resulting in more comprehensive measurements across the surface of the wafer 158.

The rectangular head-mounted sensor 172 configuration may provide flexibility in sensor design and placement within the polishing head 156. In some cases, the size and position of the head-mounted sensor 172 may be optimized based on factors such as the size of the wafer 158, the desired measurement resolution, or the specific requirements of the polishing process.

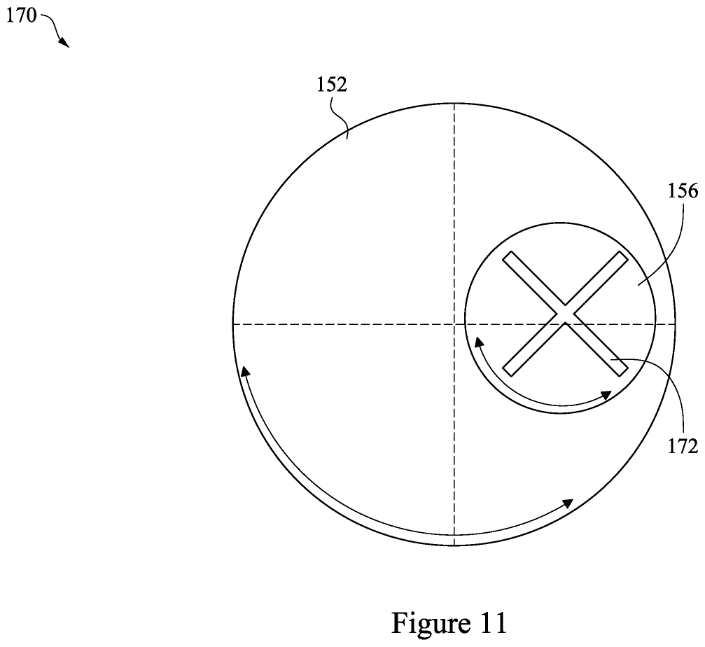

FIG. 11 illustrates a top view of a polishing system 170 configuration. In this configuration, the head-mounted sensor 172 is X-shaped in a top view. The head-mounted sensor 172 may be integrated into the polishing head 156 and may be configured to measure capacitance during polishing operations.

The X-shaped design of the head-mounted sensor 172 may provide several advantages for capacitive measurements during the polishing process. In some cases, the X-shape may allow for a larger sensing area compared to other sensor shapes, potentially improving the accuracy and sensitivity of the capacitance measurements. The X-shape may also enable measurements at multiple points across the surface of the wafer 158 simultaneously. In some cases, the X-shaped sensor may rotate with the polishing head 156, providing capacitance measurements at various orientations relative to the wafer 158.

In some cases, the controller 162 may be configured to process the capacitance measurements from the X-shaped head-mounted sensor 172. The controller 162 may use these measurements to monitor the progress of the polishing process and make adjustments to polishing parameters as needed. The X-shape of the sensor may provide data from multiple directions, potentially allowing for more comprehensive monitoring of the polishing process.

The X-shape of the head-mounted sensor 172 may demonstrate the flexibility in sensor design that may be employed in the polishing system 170. While this configuration shows an X-shaped sensor, other shapes may also be used, depending on the specific requirements of the polishing process and the desired measurement characteristics.

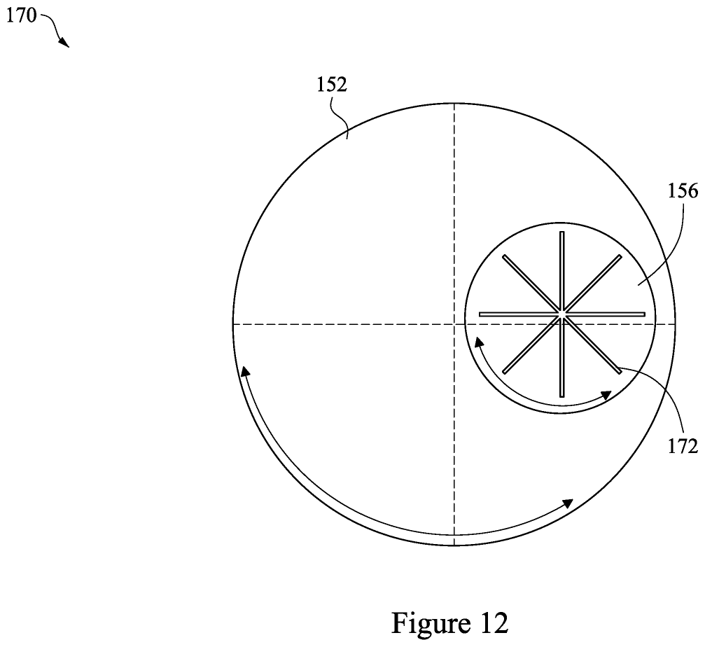

FIG. 12 illustrates a top view of a polishing system 170 configuration. In this configuration, the head-mounted sensor 172 is integrated into the polishing head 156 and has a spoke-like shape extending radially from the center of the polishing head 156 in a top view. The spoke-like shape of the head-mounted sensor 172 may provide several advantages for capacitive measurements during the polishing process. In some cases, the radial arrangement of the sensor may allow for measurements at multiple points across the radius of the wafer 158, potentially providing a more comprehensive profile of the layer to be polished.

The radial arrangement of the head-mounted sensor 172 may allow for detection of capacitance variations across different regions of the wafer 158. In some cases, this configuration may provide insights into the uniformity of the polishing process from the center to the edge of the wafer 158.

The spoke-like shape of the head-mounted sensor 172 may also offer flexibility in sensor design. In some cases, the number and length of the spokes may be optimized based on factors such as the size of the wafer 158, the desired measurement resolution, or the specific requirements of the polishing process.

In some cases, the controller 162 may be configured to process the capacitance measurements from different spokes of the head-mounted sensor 172 independently. The controller 162 may use these measurements to monitor the progress of the polishing process across different regions of the wafer 158 and make adjustments to polishing parameters as needed.

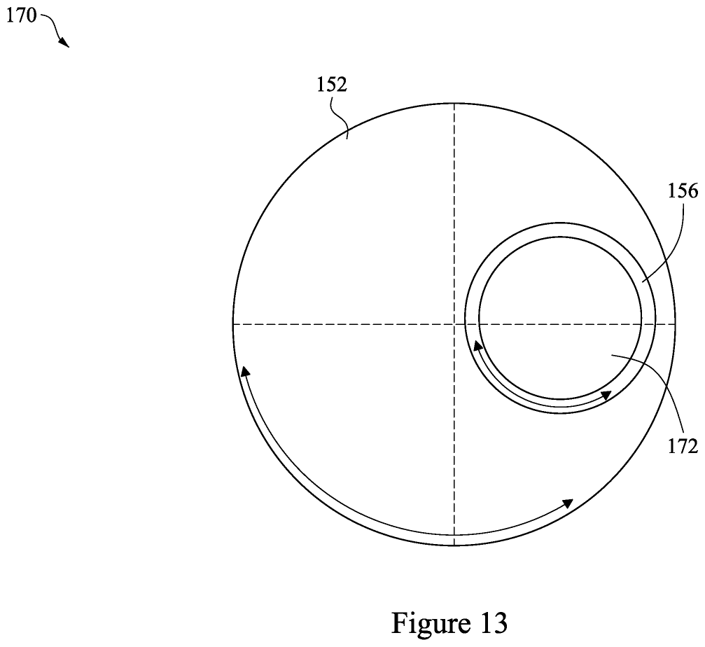

FIG. 13 illustrates a top view of a polishing system 170 configuration. In this configuration, the head-mounted sensor 172 has a circular shape in a top view and is integrated within the polishing head 156. The arrangement shows the relative positioning of these components from an overhead perspective, with dashed lines indicating the center axes of the circular platen.

The circular shape of the head-mounted sensor 172 may provide several advantages for capacitive measurements during the polishing process. In some cases, the circular shape may allow for uniform sensing across the surface of the wafer as the polishing head 156 rotates. This uniformity may contribute to more consistent and accurate measurements of the layer to be polished.

In some cases, the controller may be configured to process the capacitance measurements from the circular head-mounted sensor 172 as the polishing head 156 moves across the polishing platen 152. The controller may use these measurements to monitor the progress of the polishing process and make adjustments to polishing parameters as needed.

The circular head-mounted sensor 172 configuration may provide flexibility in sensor design and placement within the polishing head 156. In some cases, the size and position of the head-mounted sensor 172 may be optimized based on factors such as the size of the wafer, the desired measurement resolution, or the specific requirements of the polishing process.

In the embodiments illustrated in FIGS. 2-13, the CMP systems include a single polishing head (e.g., the polisher head 156) and a single polishing pad (e.g., the polishing pad 154). In some embodiments, a CMP system of the present disclosure may include multiple polisher heads and/or multiple polishing pads. In embodiments in which a CMP system includes multiple polisher heads and a single polishing pad, multiple workpieces (e.g., the wafers 100 or 158) may be polished at a same time. In embodiments in which a CMP system includes a single polisher head and multiple polishing pads, a CMP process may be a multi-step process, with each of the polishing pads having a different abrasiveness. In such embodiments, a first polishing pad may be used for bulk material removal from a workpiece, a second polishing pad may be used for global planarization of the workpiece, and a third polishing pad may be used to buff a surface of the workpiece.

The disclosed embodiments present an approach to CMP that addresses the challenge of precise dielectric film thickness control. The system utilizes in-situ capacitive measurement to monitor the thickness of dielectric films during the CMP process, enabling more accurate endpoint detection and better control of the final film thickness. This method is particularly beneficial for advanced semiconductor manufacturing processes, such as those used in advanced fabrication, where precise control of dielectric layers is critical.

The disclosed CMP system incorporates a capacitive sensor that can be integrated into either the polishing platen or the polishing head. This sensor measures the capacitance of the wafer during the polishing process, providing real-time feedback on the thickness of the dielectric film being polished. A controller processes this capacitance data and uses it to adjust polishing parameters or determine when to halt the polishing process.

In some embodiments, the method of operating the disclosed systems includes: Placing a wafer on a polishing pad of a CMP apparatus; Performing a removing process on the wafer using the CMP apparatus; Detecting the capacitance of the wafer during the removing process using a capacitive sensor; Adjusting polishing parameters based on the detected capacitance. These parameters may include polishing pressure, polishing speed, or slurry composition; and Halting the removing process when the detected capacitance of the wafer is within a predetermined range, indicating that the desired film thickness has been achieved.

The capacitive sensor may be designed to measure both platen and film capacitance, subtracting the platen capacitance to obtain the dielectric film capacitance. In some cases, the sensor may be mixed or movable to achieve the best capacitance measurement.

This approach to CMP offers several advantages over traditional methods. It provides non-contact, non-destructive measurements that can be performed continuously during the polishing process. The system is particularly well-suited for dielectric materials and can be easily integrated into existing CMP equipment. By enabling more precise control of the polishing process, this method can help reduce variations in device performance and increase overall yield in semiconductor manufacturing.

FIGS. 14 through 20 provide a description of forming a complementary field-effect transistor (CFET) structure. The disclosed CMP system and method may be utilized in the formation of the CFET structure as it can have very strict specifications for the planarization processes in its fabrication process. However, the disclosed CMP system and method are not limited to CFETs, but may be utilized in other types of devices, such as a FinFET, a Nano-FET, or the like.

FIG. 14 illustrates an example of CFETs 210 (including FETs (transistors) 210U and 210L) in accordance with some embodiments. FIG. 14 is a three-dimensional view, wherein some features of the CFETs are omitted for illustration clarity.

The CFETs include multiple vertically stacked FETs. For example, a CFET may include a lower nanostructure-FET 210L of a first device type (e.g., n-type/p-type) and an upper nanostructure-FET 210U of a second device type (e.g., p-type/n-type) that is opposite the first device type. The nanostructure-FETs 210U and 210L include semiconductor nanostructures 226 (including lower semiconductor nanostructures 226L and upper semiconductor nanostructures 226U), where the semiconductor nanostructures 226 act as the channel regions for the nanostructure-FETs. The lower semiconductor nanostructures 226L are for the lower nanostructure-FET 210L, and the upper semiconductor nanostructures 226U are for the upper nanostructure-FET 210U. In other embodiments, the CFETs may be applied to other types of transistors (e.g., FinFETs, or the like) as well.

Gate dielectrics 278 encircle the respective semiconductor nanostructures 226. Gate electrodes 280 (including a lower gate electrode 280L and an upper gate electrode 280U) are over the gate dielectrics 278. Source/drain regions 262 (including lower source/drain regions 262L and upper source/drain regions 262U) are disposed on opposing sides of the gate dielectrics 278 and the respective gate electrodes 280. The source/drain region may refer to a source or a drain, individually or collectively dependent upon the context. Isolation features (not shown) may be formed to separate desired ones of the source/drain regions 262 and/or desired ones of the gate electrodes 280.

FIG. 14 further illustrates a reference cross-section that is used in later figures. Cross-section A-A′ is a vertical cross-section that is parallel to a longitudinal axis of the semiconductor nanostructures 226 of a CFET and in a direction of, for example, a current flow between the source/drain regions 262 of the CFET. Subsequent figures may refer to this reference cross-section for clarity.

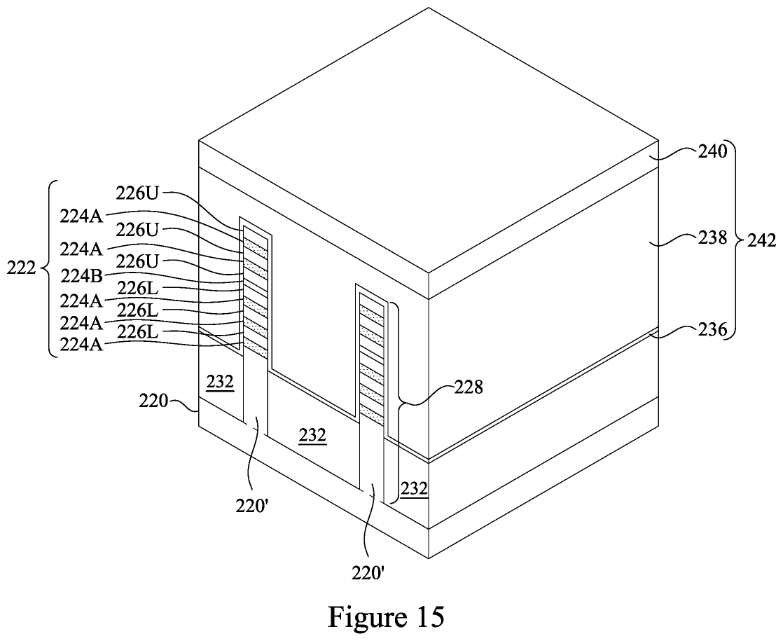

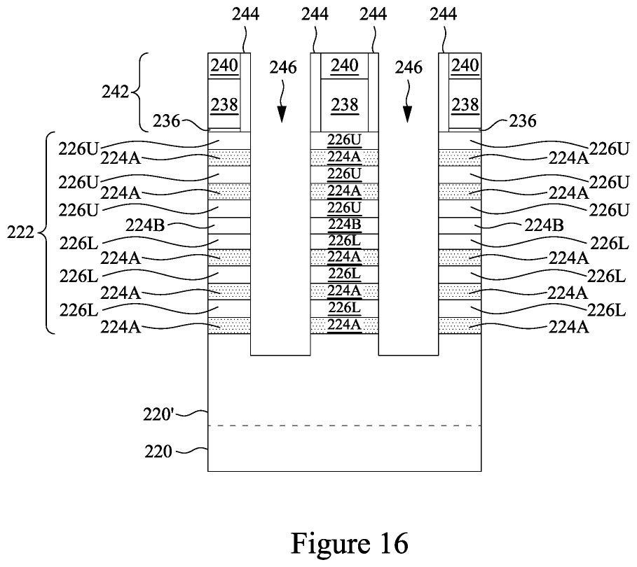

FIGS. 15 through 20 illustrate the cross-sectional views of intermediate stages in the formation of CFETs (as schematically represented in FIG. 14) in accordance with some embodiments. FIGS. 16 through 20 illustrate the vertical cross-sectional views along a similar cross-section as vertical reference cross-section A-A′ in FIG. 14.

In FIG. 15, a wafer, which includes substrate 220, is provided. Substrate 220 may be a semiconductor substrate, such as a bulk semiconductor, a semiconductor-on-insulator (SOI) substrate, or the like, which may be doped (e.g., with a p-type or an n-type dopant) or undoped. The SOI substrate may include a layer of a semiconductor material formed on an insulator layer. The insulator layer may be, for example, a buried oxide (BOX) layer, a silicon oxide layer, or the like. The insulator layer is provided on a substrate, such as a silicon or glass substrate. Other substrates, such as a multi-layered or gradient substrate may also be used. In some embodiments, the semiconductor material of the substrate 220 may include silicon, germanium, carbon-doped silicon, a III-V compound semiconductor; or the like, or combinations thereof.

Semiconductor strips 228 are formed extending upwards from the semiconductor substrate 220. Each of semiconductor strips 228 includes semiconductor strip 220′ (patterned portions of the semiconductor substrate 220) and multi-layer stack 22. The stacked component of the multi-layers stack 22 is referred to as nanostructures hereinafter. Specifically, the multi-layer stack 22 includes dummy nanostructures 224A, dummy nanostructures 224B, lower semiconductor nanostructures 226L, and upper semiconductor nanostructures 226U. Dummy nanostructures 224A and dummy nanostructures 224B may further be collectively referred to as dummy nanostructures 224 and the lower semiconductor nanostructures 226L and the upper semiconductor nanostructures 226U may further be collectively referred to as semiconductor nanostructures 226.

The dummy nanostructures 224A are formed of a first semiconductor material, and the dummy nanostructures 224B is formed of a second semiconductor material different from the first semiconductor material. The first and second semiconductor materials may be selected from the candidate semiconductor materials of the substrate 220. The first and second semiconductor materials have a high etching selectivity to one another. As such, the dummy semiconductor layer 224B may be removed at a faster rate than the dummy semiconductor layers 224A in subsequent processes.

The semiconductor nanostructures 226 (including the lower semiconductor nanostructures 226L and upper semiconductor nanostructures 226U) are formed of one or more third semiconductor material(s). The third semiconductor material(s) may be selected from the candidate semiconductor materials of the substrate 220. The lower semiconductor nanostructures 226L and the upper semiconductor nanostructures 226U may be formed of the same semiconductor material, or may be formed of different semiconductor materials. Further, the first and second semiconductor materials of the dummy nanostructure 224 have a high etching selectivity to the third semiconductor material(s) of the semiconductor nanostructures 226. As such, the dummy nanostructure 224 may be selectively removed in subsequent process steps without significantly removing the semiconductor nanostructures 226. In some embodiments, dummy semiconductor nanostructures 224A are formed of or comprise silicon germanium, semiconductor layers 226 are formed of silicon, and dummy semiconductor nanostructures 224B may be formed of germanium or silicon germanium with a higher germanium atomic percentage than the semiconductor nanostructures 224A.

The lower semiconductor nanostructures 226L will provide channel regions for lower nanostructure-FETs of the CFETs. The upper semiconductor nanostructures 226U will provide channel regions for upper nanostructure-FETs of the CFETs. The semiconductor nanostructures 226 that are immediately above/below (e.g., in contact with) the dummy nanostructures 224B may be used for isolation and may or may not act as channel regions for the CFETs. The dummy nanostructures 224B will be subsequently replaced with isolation structures. The isolation structures and the middle semiconductor nanostructures may define boundaries of the lower nanostructure-FETs and the upper nanostructure-FETS.

To form the semiconductor strips 228, layers of the first, second, and third semiconductor materials (arranged as illustrated and described above) may be deposited over the semiconductor substrate 220. The layers of the first, second, and third semiconductor materials may be grown by a process such as Vapor Phase Epitaxy (VPE) or Molecular Beam Epitaxy (MBE), deposited by a process such as Chemical Vapor Deposition (CVD) process or an Atomic Layer deposition (ALD) process, or the like. Then, a patterning process may be applied to the layers of the first, second, and third semiconductor materials as well as the semiconductor substrate 220 to define the semiconductor strips 228, which includes the semiconductor fins 220′, the dummy nanostructure 224, and the semiconductor nanostructures 226. The semiconductor fins and the nanostructures may be patterned by any suitable method. For example, the patterning process may include one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used as an etching mask for the patterning process to etch the layers of the first, second, and third semiconductor materials and the semiconductor substrate 220. The etching may be performed by any acceptable etch process, such as a Reactive Ion Etch (RIE), Neutral Beam Etch (NBE), the like, or a combination thereof. The etching may be anisotropic.

As also illustrated by FIG. 15, STI regions 232 are formed over the substrate 220 and between adjacent semiconductor strips 228. STI regions 232 may include a dielectric liner and a dielectric material over the dielectric liner. Each of the dielectric liner and the dielectric material may include an oxide such as silicon oxide, a nitride, such as silicon nitride, the like, or a combination thereof. The formation of the STI regions 232 may include depositing the dielectric layer(s), and performing a planarization process such as a CMP process, a mechanical polishing process, or the like to remove excess portions of the dielectric materials. The deposition processes may include ALD, High-Density Plasma CVD (HDP-CVD), Flowable CVD (FCVD), the like, or a combination thereof. In some embodiments, the STI regions 232 include silicon oxide formed by an FCVD process, followed by an anneal process. Then, the dielectric layers(s) are recessed to define the STI regions 232. The dielectric layer(s) maybe recessed such that upper portions of semiconductor strips 228 (including multi-layer stacks 22) protrude higher than the remaining STI regions 232.

After the STI regions 232 are formed, dummy gate stacks 242 may be formed over and along sidewalls of the upper portions of the semiconductor strips 228 (the portions that protrude higher than the STI regions 232). Forming the dummy gate stacks 242 may include forming dummy dielectric layer 236 on the semiconductor strips 228. Dummy dielectric layer 236 may be formed of or comprise, for example, silicon oxide, silicon nitride, a combination thereof, or the like, and may be deposited or thermally grown according to acceptable techniques. A dummy gate layer 238 is formed over the dummy dielectric layer 236. The dummy gate layer 238 may be deposited, for example, through Physical Vapor Deposition (PVD), CVD, or other techniques, and then planarized, such as by a CMP process. The material of dummy gate layer 238 may be conductive or non-conductive, and may be selected from a group including amorphous silicon, polycrystalline-silicon (polysilicon), poly-crystalline silicon-germanium (poly-SiGe), or the like. A mask layer 240 is formed over the planarized dummy gate layer 238, and may include, for example, silicon nitride, silicon oxynitride, or the like. Next, the mask layer 240 may be patterned through photolithography and etching processes to form a mask, which is then used to etch and pattern dummy gate layer 238, and possibly the dummy dielectric layer 236. The remaining portions of mask layer 240, dummy gate layer 238, and dummy dielectric layer 236 form dummy gate stacks 242.

In FIG. 16, gate spacers 244 and source/drain recesses 246 are formed. FIG. 16 is a cross-sectional view taken along line A-A of FIG. 14. First, the gate spacers 244 are formed over the multi-layer stacks 22 and on exposed sidewalls of dummy gate stacks 242. The gate spacers 244 may be formed by conformally forming one or more dielectric layers and subsequently etching the dielectric layers anisotropically. The applicable dielectric materials may include silicon oxide, silicon nitride, silicon oxynitride, silicon oxycarbonitride, or the like, which may be formed by a deposition process such as CVD, ALD, or the like.

Subsequently, source/drain recesses 246 are formed in semiconductor strips 228. The source/drain recesses 246 are formed through etching, and may extend through the multi-layer stacks 22 and into the semiconductor strips 220′. The bottom surfaces of the source/drain recesses 246 may be at a level above, below, or level with the top surfaces of the isolation regions 232. In the etching processes, the gate spacers 244 and the dummy gate stacks 242 mask some portions of the semiconductor strips 228. The etching may include a single etch process or multiple etch processes. Timed etch processes may be used to stop the etching of the source/drain recesses 246 upon source/drain recesses 246 reaching a desired depth.

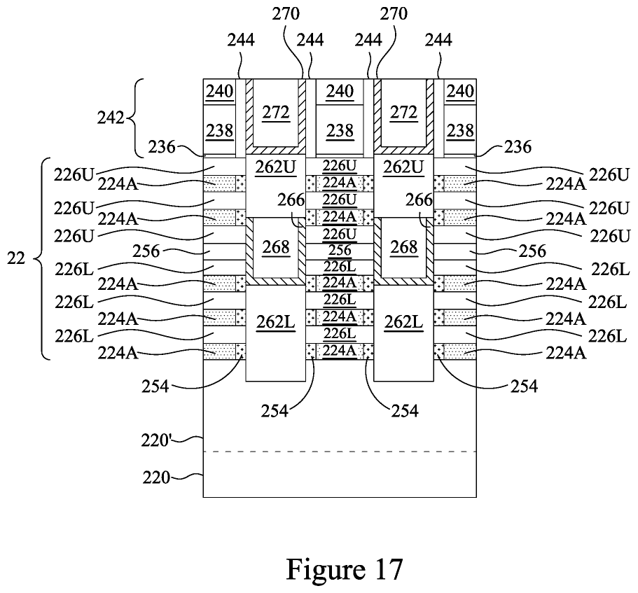

In FIG. 17, inner spacers 254 and dielectric isolation layers 256 are formed. Forming inner spacers 254 and dielectric isolation layers 256 may include an etching process that laterally etches the dummy nanostructures 224A and removes the dummy nanostructure 224B. The etching process may be isotropic and may be selective to the material of the dummy nanostructures 224, so that the dummy nanostructures 224 are etched at a faster rate than the semiconductor nanostructures 226. The etching process may also be selective to the material of the dummy nanostructures 224B, so that the dummy nanostructures 224B are etched at a faster rate than the dummy nanostructures 224A. In this manner, the dummy nanostructures 224B may be completely removed from between the lower semiconductor nanostructures 226L (collectively) and the upper semiconductor nanostructures 226U (collectively) without completely removing the dummy nanostructures 224A. In some embodiments where the dummy nanostructures 224B are formed of germanium or silicon germanium with a high germanium atomic percentage, the dummy nanostructures 224A are formed of silicon germanium with a low germanium atomic percentage, and the semiconductor nanostructures 226 are formed of silicon free from germanium, the etch process may comprise a dry etch process using chlorine gas, with or without a plasma. Because the dummy gate stacks 242 wrap around sidewalls of the semiconductor nanostructures 226 (see FIG. 15), the dummy gate stacks 242 may support the upper semiconductor nanostructures 226U so that the upper semiconductor nanostructures 226U do not collapse upon removal of the dummy nanostructures 224B. Further, although sidewalls of the dummy nanostructures 224A are illustrated as being straight after the etching, the sidewalls may be concave or convex.

Inner spacers 254 are formed on sidewalls of the recessed dummy nanostructures 224A, and dielectric isolation layers 256 are formed between the upper semiconductor nanostructures 226U (collectively) and the lower semiconductor nanostructures 226L (collectively). As subsequently described in greater detail, source/drain regions will be subsequently formed in the source/drain recesses 246, and the dummy nanostructures 224A will be replaced with corresponding gate structures. The inner spacers 254 act as isolation features between the subsequently formed source/drain regions and the subsequently formed gate structures. Further, the inner spacers 254 may be used to prevent damage to the subsequently formed source/drain regions by subsequent etch processes, such as the etch processes used to form gate structures. Dielectric isolation layers 256, on the other hand, are used to isolate the upper semiconductor nanostructures 226U (collectively) from the lower semiconductor nanostructures 226L (collectively). Further, middle semiconductor nanostructures (ones of the semiconductor nanostructures 226 in contact with the dielectric isolation layers 256) and the dielectric isolation layers 256 may define the boundaries of the lower nanostructure-FETs and the upper nanostructure-FETs.

The inner spacers 254 and the dielectric isolation layers 256 may be formed by conformally depositing an insulating material in the source/drain recesses 246, on sidewalls of the dummy nanostructures 224A, and between the upper and lower semiconductor nanostructures 226U and 226L, and then etching the insulating material. The insulating material may be a non-low-k dielectric material, which may be a carbon-containing dielectric material such as silicon oxycarbonitride, silicon oxycarbide, silicon oxynitride, or the like. The insulating material may be formed by a deposition process, such as ALD, CVD, or the like. The etching of the insulating material may be anisotropic or isotropic. The insulating material, when etched, has portions remaining in the sidewalls of the dummy nanostructures 224A (thus forming the inner spacers 254) and has portions remaining in between the upper and lower semiconductor nanostructures 226U and 226L (thus forming the dielectric isolation layers 256).

As also illustrated by FIG. 17, lower and upper epitaxial source/drain regions 262L and 262U are formed. The lower epitaxial source/drain regions 262L are formed in the lower portions of the source/drain recesses 246. The lower epitaxial source/drain regions 262L are in contact with the lower semiconductor nanostructures 226L and are not in contact with the upper semiconductor nanostructures 226U. Inner spacers 254 electrically insulate the lower epitaxial source/drain regions 262L from the dummy nanostructures 224A, which will be replaced with replacement gates in subsequent processes.

The lower epitaxial source/drain regions 262L are epitaxially grown, and have a conductivity type that is suitable for the device type (p-type or n-type) of the lower nanostructure-FETs. When lower epitaxial source/drain regions 262L are n-type source/drain regions, the respective material may include silicon or carbon-doped silicon, which is doped with an n-type dopant such as phosphorous, arsenic, or the like. When lower epitaxial source/drain regions 262L are p-type source/drain regions, the respective material may include silicon or silicon germanium, which is doped with a p-type dopant such as boron, indium, or the like. The lower epitaxial source/drain regions 262L may be in-situ doped, and may be, or may not be, implanted with the corresponding p-type or n-type dopants. During the epitaxy of the lower epitaxial source/drain regions 262L, the upper semiconductor nanostructures 226U may be masked to prevent undesired epitaxial growth on the upper semiconductor nanostructures 226U. After the lower epitaxial source/drain regions 262L are grown, the masks on the upper semiconductor nanostructures 226U may then be removed.

As a result of the epitaxy processes used for forming the lower epitaxial source/drain regions 262L, upper surfaces of the lower epitaxial source/drain regions 262L have facets which expand laterally outward beyond sidewalls of the multi-layer stacks 22. In some embodiments, adjacent lower epitaxial source/drain regions 262L remain separated after the epitaxy process is completed. In other embodiments, these facets cause neighboring lower epitaxial source/drain regions 262L of a same FET to merge.

A first contact etch stop layer (CESL) 266 and a first ILD 268 are formed over the lower epitaxial source/drain regions 262L. The first CESL 266 may be formed of a dielectric material having a high etching selectivity from the etching of the first ILD 268, such as silicon nitride, silicon oxide, silicon oxynitride, or the like, which may be formed by any suitable deposition process, such as CVD, ALD, or the like. The first ILD 268 may be formed of a dielectric material, which may be deposited by any suitable method, such as CVD, plasma-enhanced CVD (PECVD), or FCVD. The applicable dielectric material of the first ILD 268 may include phospho-silicate glass (PSG), boro-silicate glass (BSG), boron-doped phospho-silicate glass (BPSG), undoped silicate glass (USG), silicon oxide, or the like.

The formation processes may include depositing a conformal CESL layer, depositing a material for the first ILD 268, followed by a planarization process and then an etch-back process. In some embodiments, the first ILD 268 is etched first, leaving the first CESL 266 unetched. An anisotropic etching process is then performed to remove the portions of the first CESL 266 higher than the recessed first ILD 268. After the recessing, the sidewalls of the upper semiconductor nanostructures 226U are exposed.

Upper epitaxial source/drain regions 262U are then formed in the upper portions of the source/drain recesses 246. The upper epitaxial source/drain regions 262U may be epitaxially grown from exposed surfaces of the upper semiconductor nanostructures 226U. The materials of upper epitaxial source/drain regions 262U may be selected from the same candidate group of materials for forming lower source/drain regions 262L, depending on the desired conductivity type of upper epitaxial source/drain regions 262U. The conductivity type of the upper epitaxial source/drain regions 262U may be opposite the conductivity type of the lower epitaxial source/drain regions 262L. For example, the upper epitaxial source/drain regions 262U may be oppositely doped from the lower epitaxial source/drain regions 262L. The upper epitaxial source/drain regions 262U may be in-situ doped, and/or may be implanted, with an n-type or p-type dopant. Adjacent upper source/drain regions 262U may remain separated after the epitaxy process or may be merged.

After the epitaxial source/drain regions 262U are formed, a second CESL 270 and a second ILD 272 are formed. The materials and the formation methods may be similar to the materials and the formation methods of first CESL 266 and first ILD 268, respectively, and are not discussed in detail herein. The formation process may include depositing the layers for CESL 270 and ILD 272, and performing a planarization process to remove the excess portion of the corresponding layers. After the planarization process, top surfaces of the second ILD 272, the gate spacers 244, and the dummy gate stacks 242 are coplanar (within process variations). The planarization process may remove masks 240, or leave hard masks 240 unremoved.

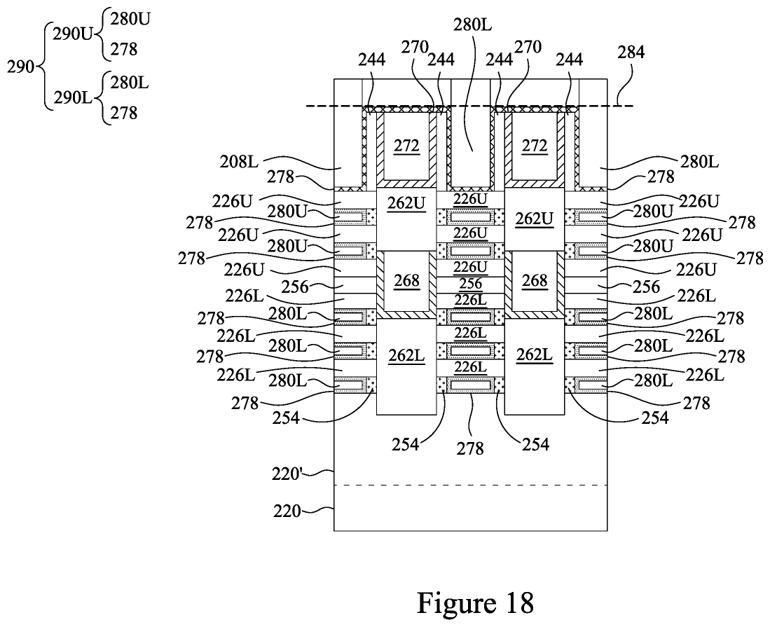

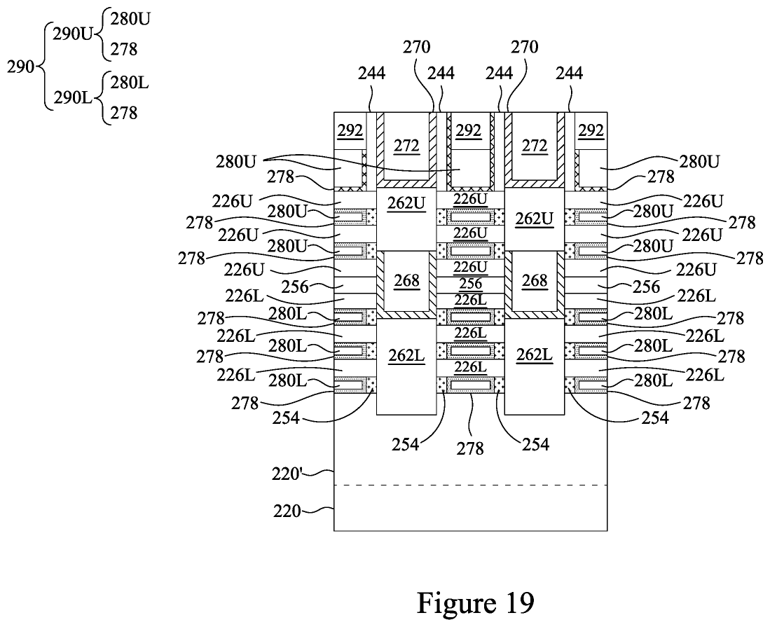

FIGS. 18 and 19 illustrate a replacement gate process to replace the dummy gate stacks 242 and the dummy nanostructures 224A with gate stacks 290. The replacement gate process includes first removing the dummy gate stacks 242 and the remaining portions of the dummy nanostructures 224A. The dummy gate stacks 242 are removed in one or more etching processes, so that recesses are defined between the gate spacers 244 and the upper portions of the semiconductor strips 228 are exposed. The remaining portions of the dummy nanostructures 224A are then removed through etching, so that the recesses extend between the semiconductor nanostructures 226. In the etching process, the dummy nanostructures 224A is etched at a faster rate than the semiconductor nanostructures 226, the dielectric isolation layers 256, and the inner spacers 254. The etching may be isotropic. For example, when the dummy nanostructures 224A are formed of silicon-germanium, and the semiconductor nanostructures 226 are formed of silicon, the etch process may include a wet etch process using tetramethylammonium hydroxide (TMAH), ammonium hydroxide (NH₄OH), or the like.

Then, gate dielectrics 278 are deposited in the recesses between the gate spacers 244 and on the exposed semiconductor nanostructures 226. The gate dielectrics 278 are conformally formed on the exposed surfaces of the recesses (the removed gate stacks 242 and the dummy nanostructures 224A) including the semiconductor nanostructures 226 and the gate spacers 244. In some embodiments, the gate dielectrics 278 wrap around all (e.g., four) sides of the semiconductor nanostructures 226. Specifically, the gate dielectrics 278 may be formed on the top surfaces of the fins 220′; on the top surfaces, the sidewalls, and the bottom surfaces of the semiconductor nanostructures 226; and on the sidewalls of the gate spacers 244. The gate dielectrics 278 may include an oxide such as silicon oxide or a metal oxide, a silicate such as a metal silicate, combinations thereof, multi-layers thereof, or the like. The gate dielectrics 278 may include a high-dielectric constant (high-k) material having a k-value greater than about 7.0, such as a metal oxide or a silicate of hafnium, aluminum, zirconium, lanthanum, manganese, barium, titanium, lead, and combinations thereof. The formation methods of the gate dielectrics 278 may include molecular-beam deposition (MBD), ALD, PECVD, and the like followed by a planarization process (e.g., a CMP) to remove portions of the gate dielectrics 278 above the second ILD 272. Although single-layered gate dielectrics 278 are illustrated, the gate dielectrics 278 may include multiple layers, such as an interfacial layer and an overlying high-k dielectric layer.

As illustrated in FIG. 18, lower gate electrodes 280L are formed on the gate dielectrics 278 around the lower semiconductor nanostructures 226L and the upper semiconductor nanostructures 226U. For example, the lower gate electrodes 280L wrap around the lower semiconductor nanostructures 226L and the upper semiconductor nanostructures 226U at this point before they will be removed from the upper semiconductor nanostructures 226U. The lower gate electrodes 280L may be formed of a metal-containing material such as tungsten, titanium, titanium nitride, tantalum, tantalum nitride, tantalum carbide, aluminum, ruthenium, cobalt, combinations thereof, multi-layers thereof, or the like. Although single-layered gate electrodes are illustrated, the lower gate electrodes 280L may include any number of work function tuning layers, any number of barrier layers, any number of glue layers, and a fill material.

The lower gate electrodes 280L are formed of material(s) that are suitable for the device type of the lower nanostructure-FETs. For example, the lower gate electrodes 280L may include one or more work function tuning layer(s) formed of material(s) that are suitable for the device type of the lower nanostructure-FETs. In some embodiments, the lower gate electrodes 280L include an n-type work function tuning layer, which may be formed of titanium aluminum, titanium aluminum carbide, tantalum aluminum, tantalum carbide, combinations thereof, or the like. In some embodiments, the lower gate electrodes 280L include a p-type work function tuning layer, which may be formed of titanium nitride, tantalum nitride, combinations thereof, or the like. Additionally or alternatively, the lower gate electrodes 280L may include a dipole-inducing element that is suitable for the device type of the lower nanostructure-FETs. Acceptable dipole-inducing elements include lanthanum, aluminum, scandium, ruthenium, zirconium, erbium, magnesium, strontium, and combinations thereof.

The lower gate electrodes 280L may be formed by conformally depositing one or more gate electrode layer(s) followed by a process of planarizing and recessing the gate electrode layer(s). The planarization process may be performed by the disclosed CMP systems and methods of FIGS. 1-13 above where the structure in FIG. 18 is the wafer 100 or 158. In some embodiments, the CMP process may remove the excess lower gate electrodes 280L over the gate dielectrics 278 over the second ILD 272. As illustrated in FIG. 18, the CMP process needs to stop at the endpoint 284 without removing the gate dielectrics 278. In some embodiments, the disclosed CMP process may remove 5 Angstroms or less of the gate dielectric 278 over the second ILD 272. The precise stopping of the disclosed CMP process is needed to provide a uniform topography for the subsequent recessing step of the lower gate electrodes 280L so that the recessing step can be better controlled and to not over etch or leave too much of the lower gate electrodes 280L in the recesses.

After the planarization process, the lower gate electrodes 280L may be recessed to around the level of the isolation layer 256. The recessing process may include any acceptable etch process, such as a dry etch, a wet etch, the like, or a combination thereof, may be performed to recess the gate electrode layer(s). The etching may be isotropic. Etching the lower gate electrodes 280L may expose the upper semiconductor nanostructures 226U.

In some embodiments, isolation layers (not explicitly illustrated) may be optionally formed on the lower gate electrodes 280L. The isolation layers act as isolation features between the lower gate electrodes 280L and subsequently formed upper gate electrodes 280U. The isolation layers may be formed by conformally depositing a dielectric material (e.g., silicon oxide, silicon nitride, silicon oxynitride, silicon oxycarbonitride, combinations thereof, or the like) and subsequently recessing the dielectric material to expose the upper semiconductor nanostructures 226U.

In FIG. 19, upper gate electrodes 280U are formed on the isolation layers described above (if present) or the lower gate electrodes 280L. The upper gate electrodes 280U are disposed between the upper semiconductor nanostructures 226U. In some embodiments, the upper gate electrodes 280U wrap around the upper semiconductor nanostructures 226U. The upper gate electrodes 280U may be formed of the same candidate materials and candidate processes for forming the lower gate electrodes 280L. The upper gate electrodes 280U are formed of material(s) that are suitable for the device type of the upper nanostructure-FETs. For example, the upper gate electrodes 280U may include one or more work function tuning layer(s) formed of material(s) that are suitable for the device type of the upper nanostructure-FETs. Although single-layered gate electrodes 280U are illustrated, the upper gate electrodes 280U may include any number of work function tuning layers, any number of barrier layers, any number of glue layers, and a fill material.

Additionally, a removal process is performed level top surfaces of the upper gate electrodes 280U and the second ILD 272. The removal process for forming the gate dielectrics 278 may be the same removal process as the removal process for forming the upper gate electrodes 280U. In some embodiments, a planarization process such as a CMP, an etch-back process, combinations thereof, or the like may be utilized. After the planarization process, the top surfaces of the upper gate electrodes 280U, the gate dielectrics 278, the second ILD 272, and the gate spacers 244 are substantially coplanar (within process variations). Each respective pair of a gate dielectric 278 and a gate electrode 280 (including an upper gate electrode 280U and/or a lower gate electrode 280L) may be collectively referred to as a “gate structure” 290 (including upper gate structures 290U and lower gate structures 290L). Each gate structure 290 extends along three sides (e.g., a top surface, a sidewall, and a bottom surface) of a channel region of a semiconductor nanostructure 226 (see FIG. 14). The lower gate structures 290L may also extend along sidewalls and/or a top surface of a semiconductor fin 220′.

As also shown in FIG. 19, gate masks 292 are formed over the gate stacks 242. The formation process may include recessing gate stacks 290, filling the resulting recesses with a dielectric material such as silicon nitride, silicon carbonitride, silicon oxynitride, silicon oxycarbonitride, or the like, and performing a planarization process to remove the excess portions of the dielectric material over the second ILD 272.

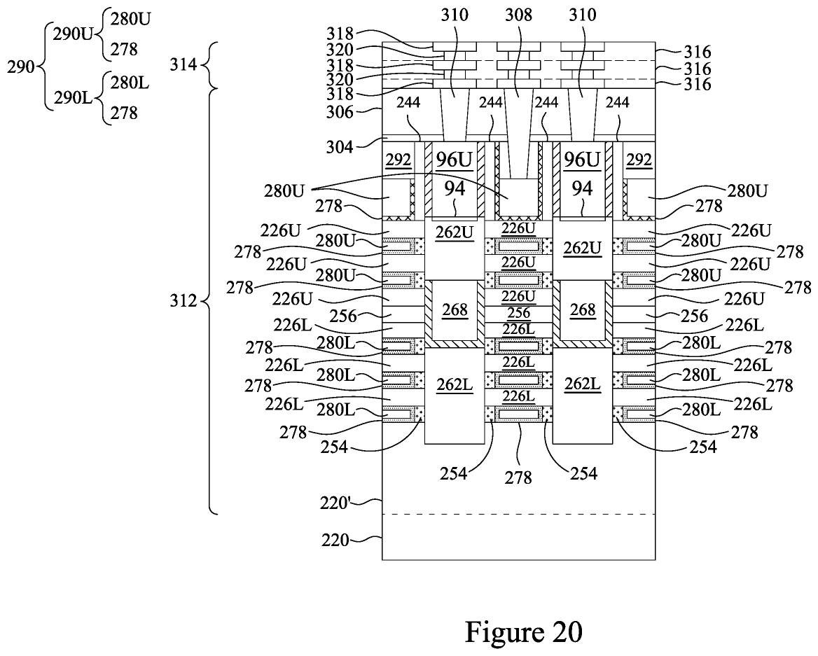

In FIG. 20, silicide regions 94 and source/drain contact plugs 96U are formed through the second ILD 272 to electrically couple to the upper epitaxial source/drain regions 262U and/or the lower epitaxial source/drain regions 262L. An etch stop layer (ESL) 304 and a third ILD 306 are the formed. In some embodiments, The ESL 304 may include a dielectric material having a high etching selectivity from the etching of the third ILD 306, such as, aluminum oxide, aluminum nitride, silicon oxycarbide, or the like. The third ILD 306 may be formed using flowable CVD, ALD, or the like, and the material may include PSG, BSG, BPSG, USG, or the like, which may be deposited by any suitable method, such as CVD, PECVD, or the like.

Subsequently, upper gate contact plugs 308 and source/drain contact plugs 310 are formed to contact the upper gate electrodes 280U and the upper source/drain contact plugs 96U, respectively. The active devices as illustrated are collectively referred to as a device layer 312.

A front-side interconnect structure 314 is formed on the device layer 312. The front-side interconnect structure 314 includes dielectric layers 316 and layers of conductive features 318/320 in the dielectric layers 316. The dielectric layers 316 may include low-k dielectric layers formed of low-k dielectric materials. The dielectric layers 316 may further include passivation layers, which are formed of non-low-k and dense dielectric materials such as Undoped Silicate-Glass (USG), silicon oxide, silicon nitride, or the like, or combinations thereof over the low-k dielectric materials. The dielectric layers 316 may also include polymer layers.

The conductive features 318/320 may include conductive lines 318 and vias 320, which may be formed using damascene processes. Conductive features 318/320 may include metal lines 318 and metal vias 320, which includes diffusion barriers and a copper containing material over the diffusion barriers. There may also be aluminum pads over and electrically connected to the metal lines and vias. Depending on how the respective die is to be packaged, the top surface features among the conductive features 318 may include bond pads, metal pillars, solder regions, and/or the like.

In some embodiments, a backside interconnect structure may be formed. The backside interconnect structure may provide electrical connection with the lower gate structures 290L and the lower epitaxial source/drain regions 262L through a backside of the device layer 312 (e.g., a side opposite to the front-side interconnect structure 314). The backside interconnect structure may be similar to the front-side interconnect structure 314 described above the description is not repeated herein. In some embodiments, the connection to the lower gate structures 290L and the lower epitaxial source/drain regions 262L be made by contacts (sometimes referred to as contact plugs) and the backside interconnect structure may be omitted.

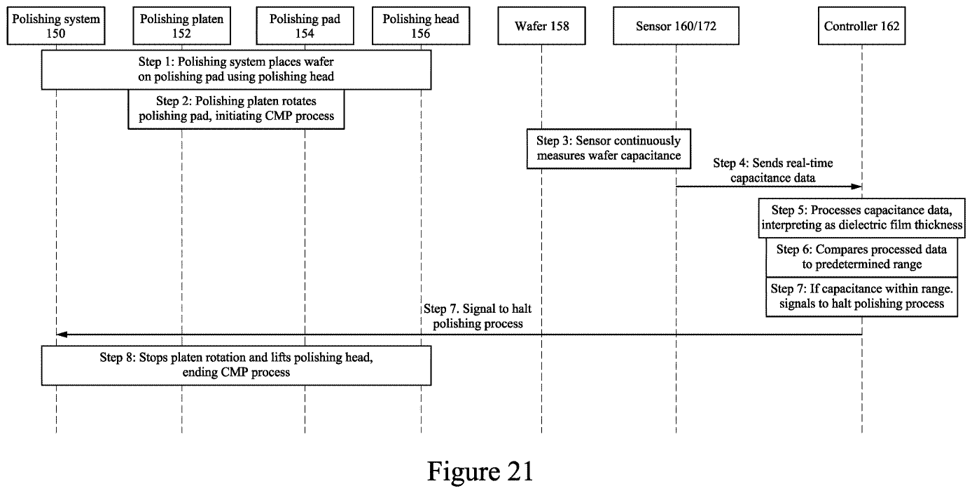

FIG. 21 illustrates a sequence diagram showing the operation of a CMP system with capacitive sensing control in accordance with some embodiments. The diagram depicts the interactions between various components of the polishing system 150, including the polishing platen 152, polishing pad 154, polishing head 156, wafer 158, sensor 160/172 (which may be platen-mounted or head-mounted), and controller 162.

Step 1 begins with the polishing system 150 placing a wafer on the polishing pad using the polishing head. In Step 2, the polishing platen 152 initiates rotation of the polishing pad 154, starting the CMP process.

As polishing occurs, Step 3 shows the sensor (160/172) continuously measuring the capacitance of the wafer 158, such as described in reference to FIG. 5 above. In Step 4, the sensor sends this capacitance data in real-time to the controller 162.

The controller then executes three processing steps: Step 5 involves processing the capacitance data and interpreting it as dielectric film thickness; in Step 6, the controller compares the processed data to a predetermined acceptable range; and in Step 7, when the capacitance measurements fall within this specified range, the controller signals to halt the polishing process.

Finally, in Step 8, upon receiving the halt signal, the system stops the platen rotation and lifts the polishing head, concluding the CMP operation.

The diagram illustrates the communication flow between components using dotted lines to indicate ongoing monitoring and solid arrows to show direct commands or actions. This sequence diagram provides a visual representation of the control loop and decision-making process involved in the capacitive sensing-based CMP system, showing how the various components interact to achieve endpoint detection and process control. The step-by-step nature of the diagram helps clarify the temporal sequence of operations and the causal relationships between different actions in the CMP process.

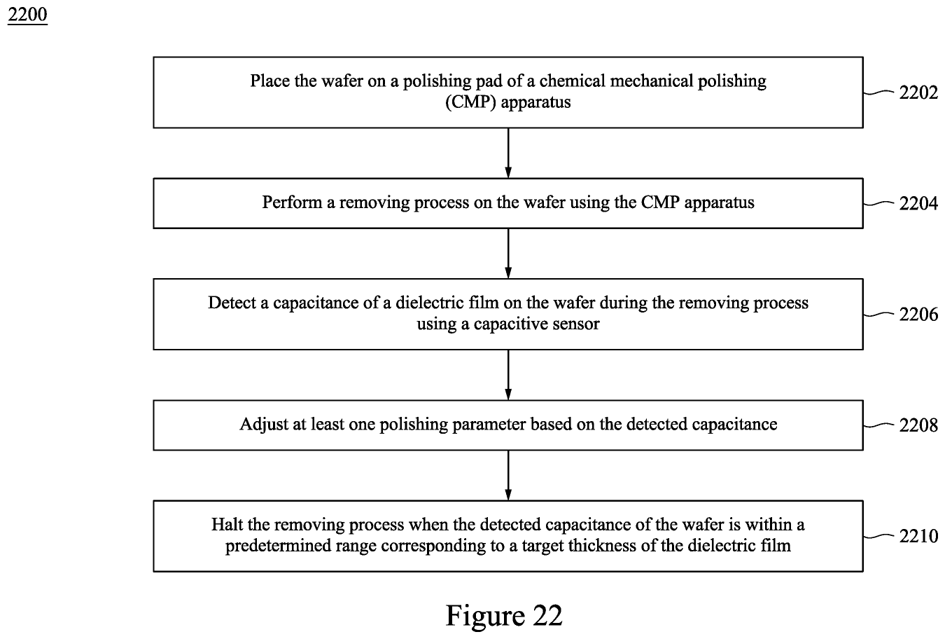

FIG. 22 is a flowchart of a process 2200 in accordance with some embodiments. In some embodiments, one or more process steps of FIG. 22 may be performed by a polishing system 150/170/180.

As shown in FIG. 22, process 2200 may include placing the wafer on a polishing pad of a chemical mechanical polishing (CMP) apparatus (step 2202). For example, polishing system 150/170/180 may place the wafer on a polishing pad of CMP apparatus, as described above. As also shown in FIG. 22, process 2200 may include performing a removing process on the wafer using the CMP apparatus (step 2204). For example, polishing system 150/170/180 may perform a removing process on the wafer using the CMP apparatus, as described above. As further shown in FIG. 22, process 2200 may include detecting a capacitance of a dielectric film on the wafer during the removing process using a capacitive sensor (step 2206). For example, polishing system 150/170/180 may detect a capacitance of a dielectric film on the wafer during the removing process using a capacitive sensor, as described above. As also shown in FIG. 22, process 2200 may include adjusting at least one polishing parameter based on the detected capacitance (step 2208). For example, polishing system 150/170/180 may adjust at least one polishing parameter based on the detected capacitance, as described above. As further shown in FIG. 22, process 2200 may include halting the removing process when the detected capacitance of the wafer is within a predetermined range corresponding to a target thickness of the dielectric film (step 2210). For example, polishing system 150/170/180 may halt the removing process when the detected capacitance of the wafer is within a predetermined range corresponding to a target thickness of the dielectric film, as described above.

Although FIG. 22 shows example steps of process 2200, in some implementations, process 2200 may include additional steps, fewer steps, different steps, or differently arranged steps than those depicted in FIG. 22. Additionally, or alternatively, two or more of the steps of process 2200 may be performed in parallel.

In an embodiment, a polishing system may include a polishing platen. The polishing system may also include a polishing pad on the polishing platen, a polishing head configured to hold a wafer in contact with the polishing pad, a capacitive sensor configured to measure a capacitance of a dielectric film on the wafer during a polishing process, and a controller electrically connected to the capacitive sensor. The controller maybe be configured to adjust at least one polishing parameter based on the measured capacitance, and halt the polishing process when the measured capacitance is within a predetermined range corresponding to a target thickness of the dielectric film.

The described embodiments may also include one or more of the following features. The polishing system where the capacitive sensor is integrated into the polishing platen. The polishing system where the capacitive sensor is integrated into the polishing head. The polishing system where the capacitive sensor may include a plurality of sensors arranged in one of: a linear configuration; a cross pattern configuration; a radial pattern configuration; or a circular pattern configuration. The polishing system may include a slurry dispenser configured to deposit slurry onto the polishing pad. The polishing system where the capacitive sensor has a shape selected from: rectangular; square; or circular. The polishing system where the at least one polishing parameter may include polishing pressure, polishing speed, or slurry composition.

In an embodiment, a method may include placing the wafer on a polishing pad of a chemical mechanical polishing (CMP) apparatus. The method may also include performing a removing process on the wafer using the CMP apparatus, detecting a capacitance of a dielectric film on the wafer during the removing process using a capacitive sensor, adjusting at least one polishing parameter based on the detected capacitance, and halting the removing process when the detected capacitance of the wafer is within a predetermined range corresponding to a target thickness of the dielectric film.

The described embodiments may also include one or more of the following features. The method where the capacitive sensor is integrated into a polishing platen of the CMP apparatus. The method where the capacitive sensor is integrated into a polishing head of the CMP apparatus. The method where the capacitive sensor may include a plurality of sensors arranged in one of: a cross pattern configuration; a radial pattern configuration; or a circular pattern configuration. The method where the at least one polishing parameter may include polishing pressure, polishing speed, or slurry composition. The method where detecting the capacitance may include measuring the capacitance at multiple locations across a surface of the wafer. The method may include depositing a slurry onto the polishing pad prior to performing the removing process.

In an embodiment, a CMP apparatus may include a capacitive sensor integrated into a polishing head, where the capacitive sensor is configured to measure a capacitance of a dielectric film on a wafer during a polishing process. The CMP apparatus may also include a controller electrically connected to the capacitive sensor, where the controller is configured to adjust at least one polishing parameter based on the measured capacitance, and halt the polishing process when the measured capacitance is within a predetermined range corresponding to a target thickness of the dielectric film.

The described embodiments may also include one or more of the following features. The CMP apparatus where the capacitive sensor may include a plurality of sensors arranged in one of: a cross pattern configuration; a radial pattern configuration; or a circular pattern configuration. The CMP apparatus where the capacitive sensor is configured to measure the capacitance at multiple locations across a surface of the wafer. The CMP apparatus where the at least one polishing parameter may include polishing pressure or polishing speed. The CMP apparatus where the capacitive sensor has a shape selected from: rectangular; square; or circular. The CMP apparatus where the capacitive sensor may include at least three sensors arranged equidistantly.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A polishing system, comprising:
a polishing platen;
a polishing pad on the polishing platen;
a polishing head configured to hold a wafer in contact with the polishing pad;
a capacitive sensor configured to measure a total capacitance during a polishing process, the total capacitance comprising a platen capacitance and a capacitance of a dielectric film on the wafer; and
a controller electrically connected to the capacitive sensor, wherein the controller is configured to:
obtain the capacitance of the dielectric film by subtracting the platen capacitance from the total capacitance;
determine a thickness of the dielectric film from the capacitance of the dielectric film using a dielectric constant of the dielectric film; and
halt the polishing process when the thickness of the dielectric film reaches a target thickness.

2. The polishing system of claim 1, wherein the capacitive sensor comprises two electrodes on opposite sides of the dielectric film, one of the two electrodes on the polishing head and another of the two electrodes on a platen-mounted sensor.

3. The polishing system of claim 1, wherein the capacitive sensor is integrated into the polishing platen.

4. The polishing system of claim 1, wherein the capacitive sensor is integrated into the polishing head.

5. The polishing system of claim 1, wherein the controller is further configured to adjust at least one polishing parameter based on the capacitance of the dielectric film.

6. The polishing system of claim 5, wherein the at least one polishing parameter comprises polishing pressure, polishing speed, or slurry composition.

7. The polishing system of claim 1, further comprising a slurry dispenser configured to deposit slurry onto the polishing pad.

8. A method of fabricating a semiconductor device, comprising:
forming a dielectric stop layer over a semiconductor feature;
forming a layer over the dielectric stop layer;
performing a chemical mechanical polishing (CMP) process to remove a portion of the layer over the dielectric stop layer;
measuring a capacitance of the dielectric stop layer using a capacitive sensor during the CMP process; and
halting the CMP process based on the measured capacitance such that 5 angstroms or less of the dielectric stop layer is removed.

9. The method of claim 8, wherein the dielectric stop layer comprises a gate dielectric, and the layer over the dielectric stop layer comprises a gate electrode material.

10. The method of claim 8, wherein the semiconductor feature comprises a semiconductor nanostructure, and the dielectric stop layer encircles the semiconductor nanostructure.

11. The method of claim 8, wherein the dielectric stop layer comprises a high-k dielectric material.

12. The method of claim 8, wherein measuring the capacitance comprises measuring the capacitance at multiple locations across a surface of a wafer that includes the semiconductor device.

13. The method of claim 8, further comprising adjusting at least one polishing parameter of the CMP process based on the measured capacitance.

14. The method of claim 8, wherein halting the CMP process comprises halting the CMP process when the measured capacitance is within a predetermined range corresponding to a target thickness of the dielectric stop layer.

15. A polishing system, comprising:
a polishing platen;
a polishing pad on the polishing platen;
a polishing head configured to hold a wafer in contact with the polishing pad;
a plurality of capacitive sensors, each capacitive sensor configured to measure a capacitance of a dielectric film on the wafer at a respective location across a surface of the wafer during a polishing process; and
a controller electrically connected to the plurality of capacitive sensors, wherein the controller is configured to:
determine a thickness of the dielectric film at each of a plurality of zones of the wafer based on the capacitance measured by the plurality of capacitive sensors; and
independently adjust at least one polishing parameter for each zone of the plurality of zones based on the determined thickness to reduce non-uniformity of material removal across the surface of the wafer.

16. The polishing system of claim 15, wherein the plurality of capacitive sensors is integrated into the polishing platen.

17. The polishing system of claim 15, wherein the plurality of capacitive sensors is arranged in one of: a linear configuration; a cross pattern configuration; a radial pattern configuration; or a circular pattern configuration.

18. The polishing system of claim 15, wherein the respective location of each capacitive sensor is at a different position along a radius of the wafer.

19. The polishing system of claim 15, wherein the at least one polishing parameter comprises polishing pressure or polishing speed.

20. The polishing system of claim 15, wherein the controller is further configured to halt the polishing process when the thickness of the dielectric film in each of the plurality of zones reaches a target thickness.
